(19) United States
(12) Patent Application Publication
(10) Pub. No.: US 2025/0359413 A1
(43) Pub. Date: Nov. 20, 2025

(54) DISPLAY PANEL AND DISPLAY APPARATUS

(71) Applicants: TIANMA ADVANCED DISPLAY TECHNOLOGY INSTITUTE (XIAMEN) CO., LTD., Xiamen (CN); SHANGHAI TIANMA MICROELECTRONICS CO., LTD., Shanghai (CN)

(72) Inventors: Zhenyu JIA, Xiamen (CN); Kerui XI, Xiamen (CN); Tianyi WU, Xiamen (CN); Bo YANG, Xiamen (CN); Yingteng ZHAI, Xiamen (CN); Yongfeng LIU, Xiamen (CN)

(21) Appl. No.: 19/245,638

(22) Filed: Jun. 23, 2025

(30) Foreign Application Priority Data
Mar. 12, 2025 (CN) 202510291025.X

(51) Int. Cl. H10H 29/49; H10D 86/40; H10D 86/60; H10H 29/32; H10K 59/121; H10K 59/131

(52) U.S. Cl. CPC H10H 29/49; H10H 29/32; H10K 59/1213; H10K 59/131; H10D 86/441; H10D 86/60

(57) ABSTRACT

Provided are a display panel and a display apparatus. The display panel comprises: a plurality of circuit rows arranged in a first direction, where at least one circuit row of the plurality of circuit rows comprises circuit regions and interval regions alternately arranged in a second direction, the circuit regions comprise pixel circuits, and the first direction intersects the second direction; and first signal lines extending in the second direction and electrically connected to the pixel circuits, where at least one of the first signal lines comprises first segments, at least one of which is located in one circuit region, and second segments, at least one of which is at least located in one interval region, and a width of at least part of the second segments in the first direction is greater than a width of at least part of the first segments in the first direction.

### CROSS-REFERENCE TO RELATED APPLICATION

The present application claims priority to Chinese Patent Application No. 202510291025.X, filed on Mar. 12, 2025, the content of which is incorporated herein by reference in its entirety.

### TECHNICAL FIELD

The present disclosure relates to the field of display technologies, and in particular, to a display panel and a display apparatus.

### BACKGROUND

A display panel includes pixels, and each pixel includes a pixel circuit and a light-emitting element. The pixel circuit is used to output a driving current to the light-emitting element, so as to drive the light-emitting element to emit light.

However, in conventional display panels, a signal line for providing a signal to a pixel circuit has a problem of larger load, which in turn is prone to poor display phenomenon caused by signal delay, attenuation, etc.

### SUMMARY

Embodiments of the present disclosure provide a display panel and a display apparatus for reducing the load on the signal line and alleviating the problems of delay and attenuation of the signal.

In a first aspect, an embodiment of the present disclosure provides a display panel, including:
a plurality of circuit rows arranged in a first direction, where at least one circuit row of the plurality of circuit rows includes circuit regions and interval regions alternately arranged in a second direction, the circuit regions includes pixel circuits, and the first direction intersects the second direction; and
first signal lines extending in the second direction and electrically connected to the pixel circuits, where at least one of the first signal lines includes first segments, at least one of which is located in one circuit region, and second segments, at least one of which is at least located in one interval region, and a width of at least part of the second segments in the first direction is greater than a width of at least part of the first segments in the first direction.

In a second aspect, based on the same inventive concept, an embodiment of the present disclosure further provides a display apparatus, including the above-mentioned display panel.

### BRIEF DESCRIPTION OF DRAWINGS

In order to more clearly illustrate technical solutions in the embodiments of the present disclosure or in the related art, the drawings required in the description of the embodiments or the related art will be briefly introduced below. Apparently, the drawings in the following description below are some embodiments of the present disclosure. For those of skill in the art, other drawings can be obtained based on these drawings without creative efforts.

FIG. 1 is a structural schematic diagram of a display panel provided by an embodiment of the present disclosure;

FIG. 2 is a structural schematic diagram of a first signal line provided by an embodiment of the present disclosure;

FIG. 3 is another structural schematic diagram of a first signal line provided by an embodiment of the present disclosure;

FIG. 4 is a further structural schematic diagram of a first signal line provided by an embodiment of the present disclosure;

FIG. 5 is a structural schematic diagram of a transistor provided by an embodiment of the present disclosure;

FIG. 6 is a cross-sectional view of FIG. 5 along a direction A1-A2;

FIG. 7 is another structural schematic diagram of a transistor provided by an embodiment of the present disclosure;

FIG. 8 is a cross-sectional view of FIG. 7 along a direction B1-B2;

FIG. 9 is a schematic diagram of a film layer structure of a display panel provided by an embodiment of the present disclosure;

FIG. 10 is another structural schematic diagram of a display panel provided by an embodiment of the present disclosure;

FIG. 11 is yet another structural schematic diagram of a first signal line provided by an embodiment of the present disclosure;

FIG. 12 is another schematic diagram of a film layer structure of a display panel provided by an embodiment of the present disclosure;

FIG. 13 is yet another structural schematic diagram of a first signal line provided by an embodiment of the present disclosure;

FIG. 14 is yet another structural schematic diagram of a first signal line provided by an embodiment of the present disclosure;

FIG. 15 is a further schematic diagram of a film layer structure of a display panel provided by an embodiment of the present disclosure;

FIG. 16 is yet another structural schematic diagram of a first signal line provided by an embodiment of the present disclosure;

FIG. 17 is yet another structural schematic diagram of a first signal line provided by an embodiment of the present disclosure;

FIG. 18 is yet another structural schematic diagram of a first signal line provided by an embodiment of the present disclosure;

FIG. 19 is yet another structural schematic diagram of a first signal line provided by an embodiment of the present disclosure;

FIG. 20 is yet another structural schematic diagram of a first signal line provided by an embodiment of the present disclosure;

FIG. 21 is yet another schematic diagram of a film layer structure of a display panel provided by an embodiment of the present disclosure;

FIG. 22 is yet another schematic diagram of a film layer structure of a display panel provided by an embodiment of the present disclosure;

FIG. 23 is yet another schematic diagram of a film layer structure of a display panel provided by an embodiment of the present disclosure;

FIG. 24 is yet another schematic diagram of a film layer structure of a display panel provided by an embodiment of the present disclosure;

FIG. 25 is yet another structural schematic diagram of a display panel provided by an embodiment of the present disclosure;

FIG. 26 is yet another structural schematic diagram of a display panel provided by an embodiment of the present disclosure;

FIG. 27 is yet another structural schematic diagram of a display panel provided by an embodiment of the present disclosure;

FIG. 28 is yet another structural schematic diagram of a display panel provided by an embodiment of the present disclosure;

FIG. 29 is yet another structural schematic diagram of a display panel provided by an embodiment of the present disclosure;

FIG. 30 is a structural schematic diagram of a first signal line corresponding to FIG. 29;

FIG. 31 is yet another structural schematic diagram of a display panel provided by an embodiment of the present disclosure;

FIG. 32 is a schematic diagram of a circuit structure of a pixel circuit provided by an embodiment of the present disclosure;

FIG. 33 is a schematic diagram of a film layer structure of a pixel circuit provided by an embodiment of the present disclosure;

FIG. 34 is yet another schematic diagram of a film layer structure of a display panel provided by an embodiment of the present disclosure;

FIG. 35 is a structural schematic diagram of a display apparatus provided by an embodiment of the present disclosure; and

FIG. 36 is another structural schematic diagram of a display apparatus provided by an embodiment of the present disclosure.

### DESCRIPTION OF EMBODIMENTS

In order to better understand the technical solutions of the present disclosure, the embodiments of the present disclosure will be described in detail below in conjunction with the accompanying drawings.

It should be clear that the described embodiments are only some of, rather than all of, the embodiments of the present disclosure. Based on the embodiments of the present disclosure, all other embodiments obtained by those of ordinary skill in the art without creative efforts shall fall within the protection scope of the present disclosure.

The terms used in the embodiments of the present disclosure are only for the purpose of describing specific embodiments and are not intended to limit the present disclosure. The singular forms “a/an”, “the” and “said” used in the embodiments of the present disclosure and the appended claims are also intended to include the plural forms, unless the context clearly indicates otherwise.

It should be understood that the term “and/or” used herein is only a description of the correlation relationship between associated objects, indicating that there can be three relationships. For example, A and/or B can mean: A exists alone, A and B exist simultaneously, and B exists alone. In addition, the character “/” herein generally indicates that the associated objects are in an “or” relationship.

The embodiments of the present disclosure provide a display panel. The display panel can be a light emitting diode (LED) display panel, an organic light emitting diode (OLED) display panel, or the like, for example, a micro LED display panel.

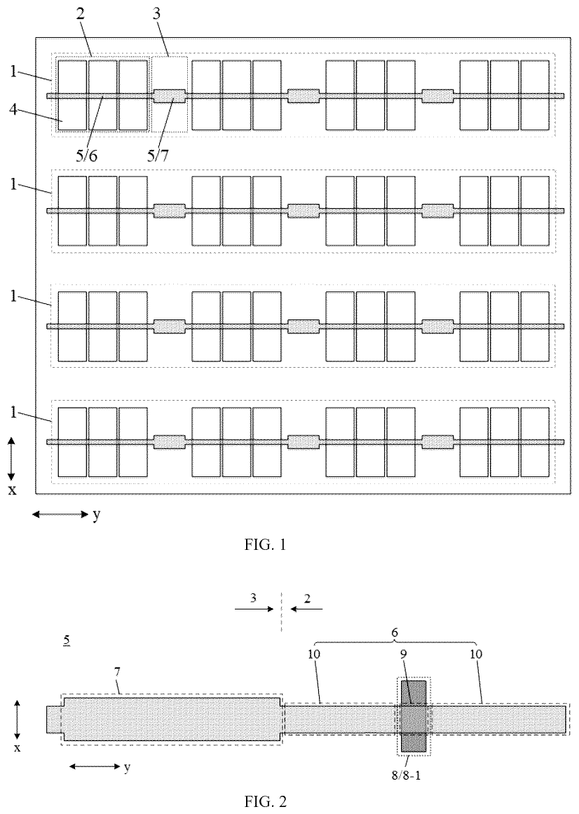

As shown in FIG. 1, which is a structural schematic diagram of a display panel provided by an embodiment of the present disclosure, the display panel includes a plurality of circuit rows 1 arranged in a first direction x. At least one of the circuit rows 1 includes circuit regions 2 and interval regions 3 alternately arranged in a second direction y, and the first direction x intersects the second direction y. The circuit regions 2 include pixel circuits 4.

The display panel further includes first signal lines 5 extending in the second direction y and electrically connected to the pixel circuits 4. At least one of the first signal lines 5 includes first segments 6 and second segments 7, where at least one of the first segments 6 is located in one circuit region 2, and at least one of the second segments 7 is at least located in one interval region 3. Moreover, a width of at least part segments of the second segments 7 in the first direction x is greater than a width of at least part segments of the first segments 6 in the first direction x.

In the related art, horizontal signal lines electrically connected to pixel circuits usually adopt an equal line width design. That is, the line width of the same horizontal signal line at different positions is consistent.

In contrast, in the embodiments of the present disclosure, a widened design is adopted for at least some horizontal signal lines. The display panel includes the first signal lines 5 extending horizontally. At least one of the first signal lines 5 includes the first segments 6, at least one of which is located in one circuit region 2, and the second segments 7, at least one of which is at least located in one interval region 3. In the embodiments of the present disclosure, a widened design is adopted for the second segments 7, such that a line width of the second segments 7 is greater than a line width of the first segments 6. In this way, the second segments 7 can be used to reduce the routing resistance of the first signal line 5, reducing the load on the first signal line 5, and further alleviating the problem of poor display caused by signal delay and attenuation in the first signal line 5.

In addition, the wiring in the circuit regions 2 is complex. If the segments of the first signal line 5 located in the circuit regions 2 are widened, the widened segments may affect the arrangement of other same-layer routings or the arrangement of some via holes, thereby leading to difficulties in layout design. In contrast, the wiring in the interval regions 3 is simple, and thus in the embodiments of the present disclosure, the segments of the first signal line 5 located in the interval regions 3 are selected to be widened, which can effectively avoid the above-mentioned problems and reduce the difficulty of layout design.

In a feasible implementation, in conjunction with FIG. 32, at least one of the pixel circuits 4 includes a plurality of transistors 8.

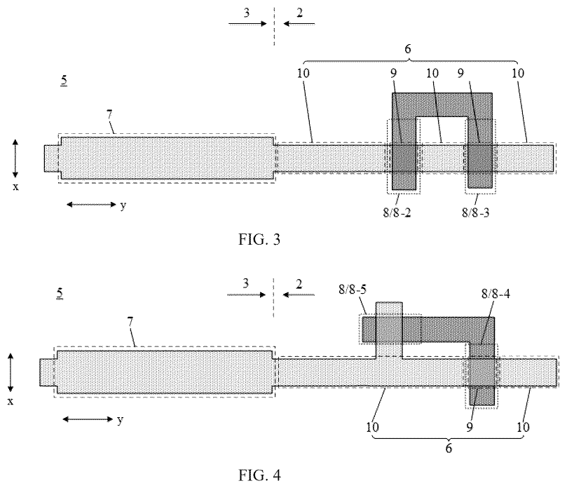

As shown in FIGS. 2 to 4, where FIG. 2 is a structural schematic diagram of a first signal line provided by an embodiment of the present disclosure, FIG. 3 is another structural schematic diagram of a first signal line provided by an embodiment of the present disclosure, and FIG. 4 is a further structural schematic diagram of a first signal line provided by an embodiment of the present disclosure, in at least part of the first signal lines 5, at least one of the first segments 6 includes a first sub-segment 9 and a second sub-segment 10 that are connected to each other. The first sub-segment 9 is reused as a gate of a transistor 8, and a channel length direction corresponding to the gate that the first sub-segment 9 is reused as is the first direction x. In these first signal lines 5, a width of the second segments 7 in the first direction x is greater than a width of the first sub-segment 9 in the first direction x.

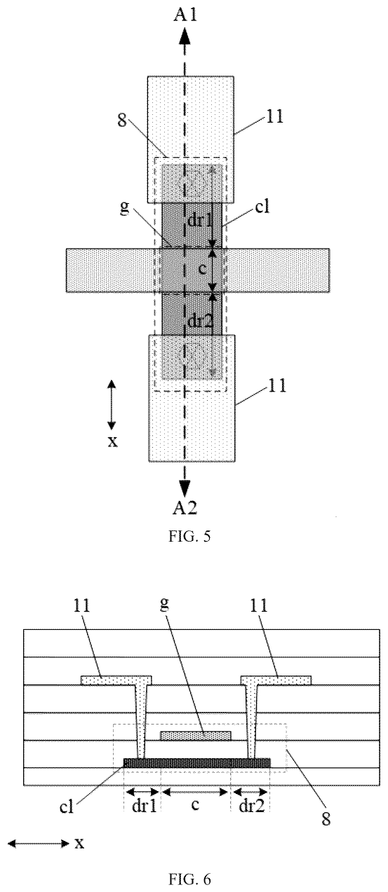

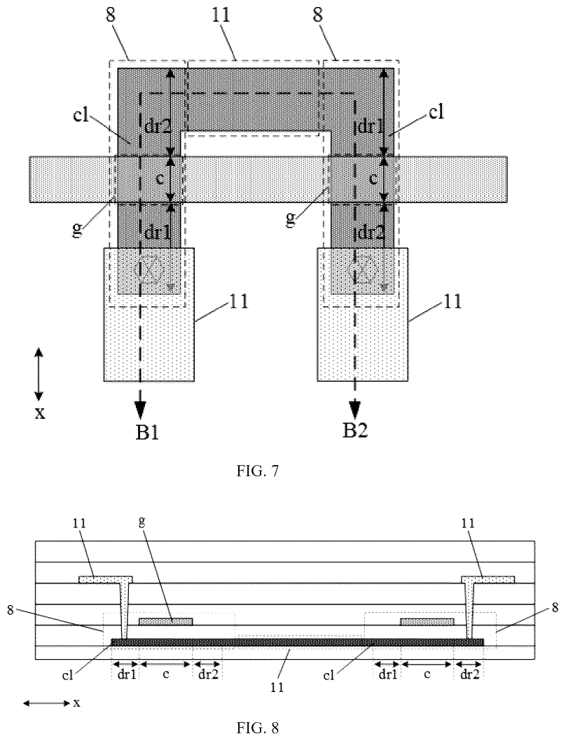

Regarding the structure of the transistor 8, as shown in FIGS. 5 to 8, where FIG. 5 is a structural schematic diagram of a transistor provided by an embodiment of the present disclosure, FIG. 6 is a cross-sectional view of FIG. 5 along a direction A1-A2, FIG. 7 is another structural schematic diagram of a transistor provided by an embodiment of the present disclosure, and FIG. 8 is a cross-sectional view of FIG. 7 along a direction B1-B2, the transistor 8 includes an active layer cl and a gate g, and the active layer cl includes a channel c, a first doped region dr1 and a second doped region dr2.

In a direction perpendicular to a plane of the display panel, the gate g coincides with the channel c.

At least one of the first doped region dr1 and the second doped region dr2 is connected to a connection lead 11. Referring to FIGS. 5 and 6, the connection lead 11 can be disposed in a different layer from the active layer cl. Alternatively, referring to FIGS. 7 and 8, the connection lead 11 can also be disposed in the same layer as the active layer cl. A channel length of the transistor 8 is a distance between the first doped region dr1 and the second doped region dr2, and the channel length direction of the transistor 8 is the first direction x, which means that an arrangement direction of the first doped region dr1 and the second doped region dr2 of the transistor 8 is the first direction x.

In addition, the pixel circuit 4 can include a single-gate transistor and a dual-gate transistor. For example, the transistor 8 illustrated in FIG. 5 is a single-gate transistor, and the two transistors 8 illustrated in FIG. 6 form a dual-gate transistor. The two transistors 8 in the dual-gate transistor are connected in series, and the gates of the two transistors 8 are electrically connected to each other.

The first sub-segment 9 in the first signal line 5 is explained in the following with respect to the single-gate transistor and the dual-gate transistor.

Referring to FIG. 2, in one structure, the transistor 8 includes a first sub-transistor 8-1. The first sub-transistor 8-1 is a single-gate transistor, and a channel length direction of the first sub-transistor 8-1 is the first direction x. In at least one of the first signal lines 5, at least a part of the first sub-segment 9 in the first segment 6 is reused as a gate of the first sub-transistor 8-1.

Referring to FIG. 3, in one structure, the transistor 8 includes a second sub-transistor 8-2 and a third sub-transistor 8-3. The second sub-transistor 8-2 and the third sub-transistor 8-3 form a dual-gate transistor, and the channel length directions of both the second sub-transistor 8-2 and the third sub-transistor 8-3 are the first direction x. In at least one of the first signal lines 5, a part of the first sub-segment 9 in the first segment 6 is reused as a gate of the second sub-transistor 8-2, and a part of the first sub-segment 9 in the first segment 6 is reused as a gate of the third sub-transistor 8-3.

Referring to FIG. 4, in one structure, the transistor 8 includes a fourth sub-transistor 8-4 and a fifth sub-transistor 8-5. The fourth sub-transistor 8-4 and the fifth sub-transistor 8-5 form a dual-gate transistor, where a channel length direction of the fourth sub-transistor 8-4 is the first direction x, and a channel length direction of the fifth sub-transistor 8-5 is the second direction y. In at least one of the first signal lines 5, at least a part of the first sub-segment 9 in the first segment 6 is reused as a gate of the fourth sub-transistor 8-4. It should be noted that in this structure, a gate of the fifth sub-transistor 8-5 protrudes from the first segment 6 in the first direction x, and this gate does not belong to the first segment 6.

The following takes a film layer structure of the pixel circuit 4 as an example to further illustrate the first signal line 5.

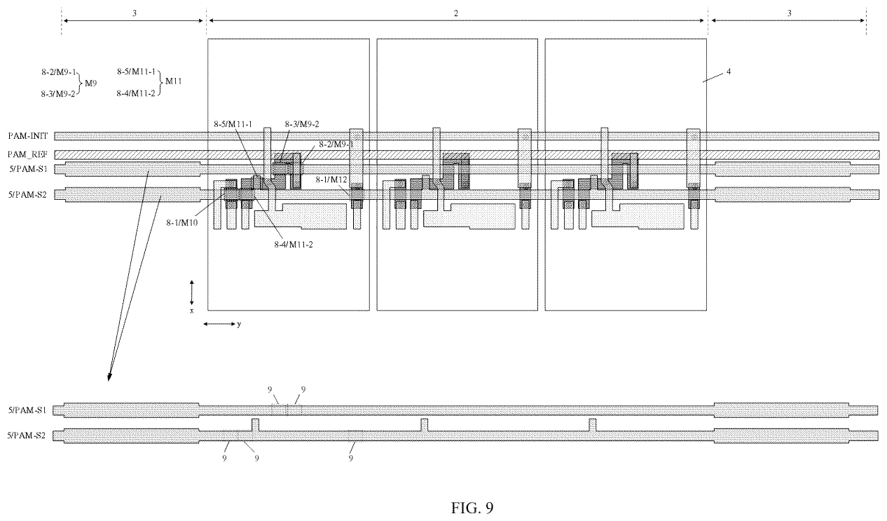

In conjunction with FIGS. 32 to 34, as shown in FIG. 9, which is a schematic diagram of a film layer structure of a display panel provided by an embodiment of the present disclosure, the pixel circuit 4 includes a second gate reset transistor M9, a second data writing transistor M10, a second threshold compensation transistor M11, and an anode reset transistor M12. In subsequent embodiments, the connection relationship of this part of the transistors 8 will be described.

The second data writing transistor M10 and the anode reset transistor M12 are the first sub-transistors 8-1.

The second gate reset transistor M9 is a dual-gate transistor. The second gate reset transistor M9 includes a first reset sub-transistor M9-1 and a second reset sub-transistor M9-2 connected in series, where the first reset sub-transistor M9-1 is the second sub-transistor 8-2, and the second reset sub-transistor M9-2 is the third sub-transistor 8-3.

The second threshold compensation transistor M11 is a dual-gate transistor. The second threshold compensation transistor M11 includes a first compensation sub-transistor M11-1 and a second compensation sub-transistor M11-2 connected in series, where the first compensation sub-transistor M11-1 is the fifth sub-transistor 8-5, and the second compensation sub-transistor M11-2 is the fourth sub-transistor 8-4.

The first signal lines 5 include a second reset scanning line PAM-S1. A part of the first sub-segment 9 in the second reset scanning line PAM-S1 is reused as a gate of the first reset sub-transistor M9-1, and a part of the first sub-segment 9 in the second reset scanning line PAM-S1 is reused as a gate of the second reset sub-transistor M9-2. Moreover, the width of the second segment 7 in the second reset scanning line PAM-S1 in the first direction x is greater than the width of the first sub-segment 9 in the first direction x.

The first signal lines 5 include a second compensation scanning line PAM-S2. A part of the first sub-segment 9 in the second compensation scanning line PAM-S2 is reused as a gate of the second compensation sub-transistor M11-2, a part of the first sub-segment 9 in the second compensation scanning line PAM-S2 is reused as a gate of the second data writing transistor M10, and a part of the first sub-segment 9 in the second compensation scanning line PAM-S2 is reused as a gate of the anode reset transistor M12. Moreover, the width of the second segment 7 in the second compensation scanning line PAM-S2 in the first direction x is greater than the width of the first sub-segment 9 in the first direction x.

In the above structure, at least part of the first signal lines 5 in the display panel are scanning lines for providing gate signals to the transistors 8. These first signal lines 5 are used for controlling the on and off of the transistors 8, and the signal quality thereof has a greater influence on the stability of the pixel circuits 4. Therefore, after reducing the load on these first signal lines 5, the display effect can be greatly improved.

Moreover, in the embodiments of the present disclosure, the first sub-segments 9 in these first signal lines 5 that are reused as the gates of the transistors are not widened. The width of the first sub-segments 9 still follows the design requirements of the channel width-to-length ratio of their corresponding transistors 8. Therefore, the load on these first signal lines 5 is reduced without affecting the device size of the transistors 8 connected thereto.

Further, referring to FIGS. 2 to 4 again, in the first segment 6, a width of the second sub-segment 10 in the first direction x is equal to the width of the first sub-segment 9 in the first direction x.

That is, in the embodiments of the present disclosure, all of the segments of the first signal line 5 located in the circuit regions 2 are not widened, and only the segments located in the interval regions 3 are widened, which not only avoids the influence on the arrangement of the original wiring and via holes in the pixel circuits 4, but also avoids the increase of the parasitic capacitance between the first signal line 5 and the pixel circuits 4.

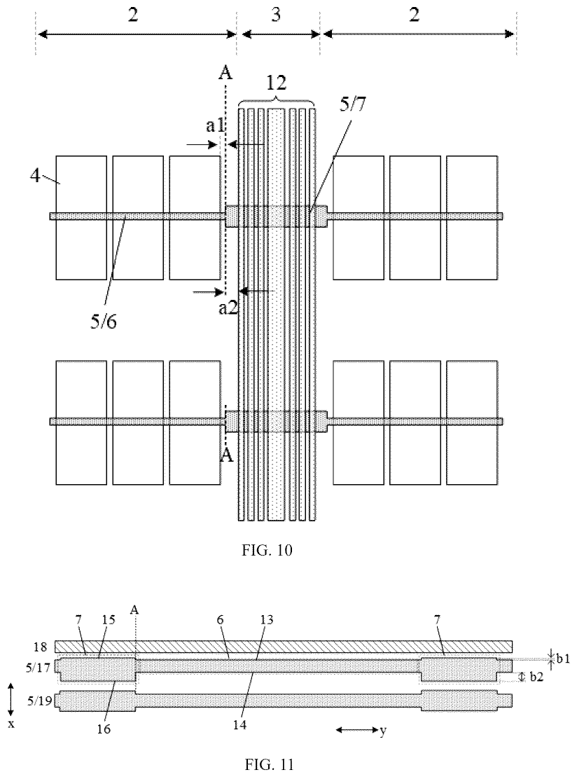

In a feasible implementation, as shown in FIG. 10, which is another structural schematic diagram of a display panel provided by an embodiment of the present disclosure, the display panel further includes second signal lines 12 extending in the first direction x and located in the interval regions 3.

At least part of the second signal lines 12 are electrically connected to the pixel circuits 4. For example, referring to FIGS. 32 to 34, the second signal lines 12 may include at least one of a first data line PWM-Data, a second data line PWM-Data, a first reset line PWM-REF, a second reset line PAM-REF, an anode reset line PAM-INIT, a first power line PWM-vdd, and a second power line PAM-vdd.

In at least part of the first signal lines 5, a junction A between one second segment of the second segments 7 and one first segment of the first segments 6 is located in one interval region of the interval regions 3, and a distance a1 between the junction A and one pixel circuit of the pixel circuits 4 that is adjacent thereto is less than a distance a2 between the junction and one second signal line of the second signal lines 12 that is adjacent thereto.

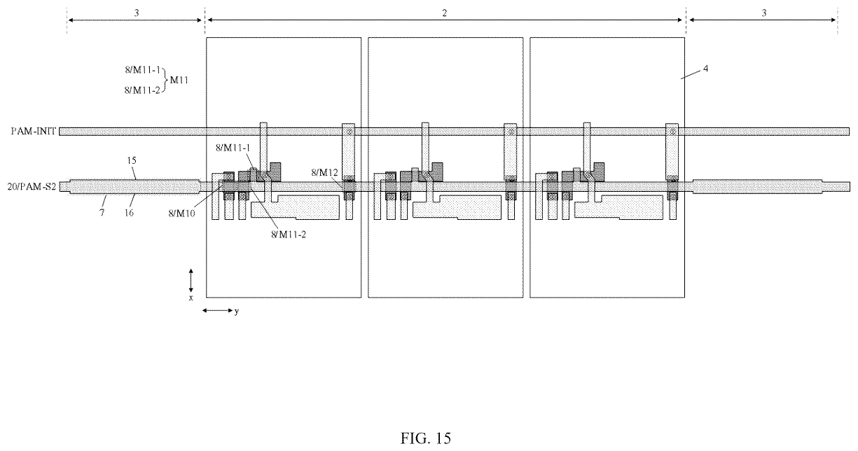

The junction A between the first segment 6 and the second segment 7 can be understood as the position where the line width of the first signal line 5 starts to change in the interval region 3. For example, referring to FIGS. 11 and 14, the junction A is the connection position between a first side 13 of the first segment 6 and a third side 15 of the second segment 7.

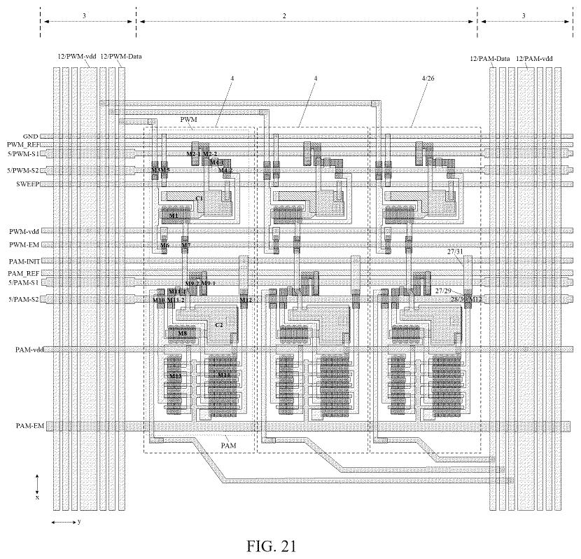

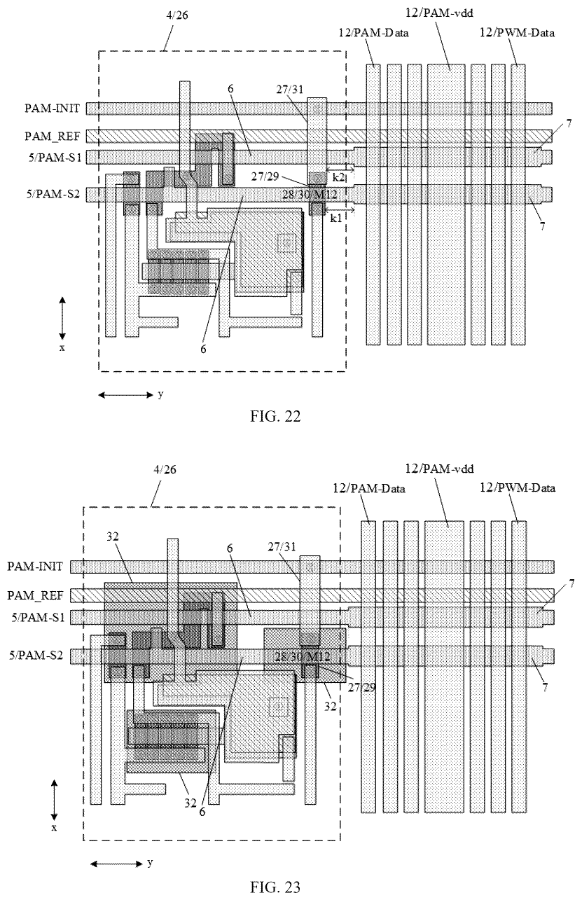

The distance a1 between the junction A and the pixel circuit 4 can be understood as the distance between the second segment 7 and the wiring in the pixel circuit 4 closest thereto. For example, referring to FIGS. 21 and 22, the distance a1 is the distance between the second segment 7 and a first routing 27.

The distance a2 between the junction A and the second signal line 12 adjacent thereto can be understood as the distance between the first segment 6 and the second signal line 12 closest thereto.

When the first signal line 5 is widened, making a widened portion closer to the pixel circuit 4 can make a widened segment have a greater length, so that the widened segment can play a greater role in reducing the load on the first signal line 5.

In some embodiments, as shown in FIG. 11, which is yet another structural schematic diagram of a first signal line provided by an embodiment of the present disclosure, at least one of the first segments 6 includes a first side 13 and a second side 14 opposite to each other in the first direction x, and at least one of the second segments 7 includes a third side 15 and a fourth side 16 opposite to each other in the first direction x and both extending in the second direction y.

The first signal lines 5 include a first-type of first signal line 17. In the first-type of first signal line 17, a distance b1 between the first side 13 and an extension line of the third side 15 is less than a distance b2 between the second side 14 and an extension line of the fourth side 16.

In the above arrangement, the second segments 7 in the first-type of first signal line 17 have different widening degrees on both sides, which reduces the load on the first-type of first signal line 17 and at the same time can allow the widened segments to more flexibly match the wiring conditions of other routings on both sides of the first-type of first signal line 17. For example, when the first-type of first signal line 17 is very close to other routings on a certain side, the second segments 7 can be widened only to a lesser extent or not be widened on that side, thereby ensuring that a sufficient distance is maintained between the second segments 7 and the adjacent routing on that side to avoid larger coupling.

In a feasible implementation, referring to FIG. 11 again, the display panel further includes a third signal line 18 and a fourth signal line 19.

The third signal line 18 extends in the second direction y and is adjacent to the first-type of first signal line 17 on one side of the first side 13. That is, the third signal line 18 is a horizontal signal line closest to the first-type of first signal line 17 on one side of the first side 13, and there is no other horizontal signal line between the third signal line 18 and the first-type of first signal line 17.

The fourth signal line 19 extends in the second direction y and is adjacent to the first-type of first signal line 17 on one side of the second side 14. That is, the fact that the fourth signal line 19 is adjacent to the first-type of first signal line 17 on one side of the second side 14 means that the fourth signal line 19 is a horizontal signal line closest to the first-type of first signal line 17 on one side of the second side 14, and there is no other horizontal signal line between the fourth signal line 19 and the first-type of first signal line 17.

A distance between the third signal line 18 and the first side 13 is less than a distance between the fourth signal line 19 and the second side 14.

When the first-type of first signal line 17 is closer to the adjacent horizontal signal line on the one side of the first side 13, the second segments 7 in the first-type of first signal line 17 are widened to a lesser extent or not widened on that side, which can avoid the increase of the parasitic capacitance between the second segments 7 and the third signal line 18.

It should be noted that the third signal line 18 and/or the fourth signal line 19 can also be the first signal line 5. That is to say, the third signal line 18 and/or the fourth signal line 19 can also adopt the widening design provided by the embodiments of the present disclosure.

In a feasible implementation, referring to FIG. 11 again, the display panel further includes a third signal line 18. The third signal line 18 extends in the second direction y and is adjacent to the first-type of first signal line 17 on one side of the first side 13. That is, the third signal line 18 is a horizontal signal line closest to the first-type of first signal line 17 on one side of the first side 13, and there is no other horizontal signal line between the third signal line 18 and the first-type of first signal line 17.

The third signal line 18 and the first-type of first signal line 17 are disposed in different layers.

In the layout design of the display panel, when two adjacent horizontal signal lines are located in different layers, the spacing between the two horizontal signal lines is usually set to be relatively small because the problem of short circuit between the two horizontal signal lines does not need to be considered. When the first-type of first signal line 17 and the third signal line 18 adjacent thereto on the one side of the first side 13 are located in different layers, the second segments 7 in the first-type of first signal line 17 are widened to a lesser extent or not widened on that side, which can avoid the increase of the parasitic capacitance between the second segments 7 and the third signal line 18.

The following takes a film layer structure of the pixel circuit 4 as an example to schematically illustrate the first-type of first signal line 17.

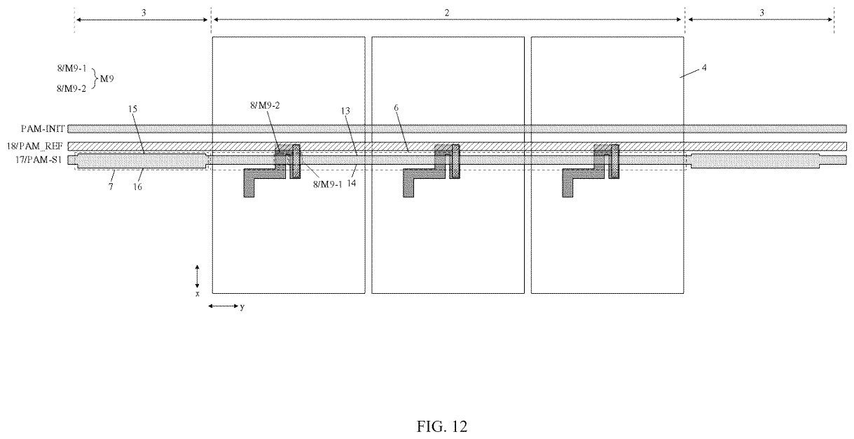

As shown in FIG. 12, which is another schematic diagram of a film layer structure of a display panel provided by an embodiment of the present disclosure, the first-type of first signal line 17 includes the second reset scanning line PAM-S1, and the third signal line 18 includes the second reset line PAM-REF. The second reset scanning line PAM-S1 is adjacent to the second reset line PAM-REF on one side of the first side 13, and the second reset line PAM-REF and the second reset scanning line PAM-S1 are disposed in different layers.

In the second reset scanning line PAM-S1, the second segments 7 are widened to a lesser extent or not widened on the one side close to the second reset line PAM-REF, and are widened to a larger extent on one side away from the second reset line PAM-REF, so as to avoid the increase of the parasitic capacitance between the second reset scanning line PAM-S1 and the second reset line PAM-REF.

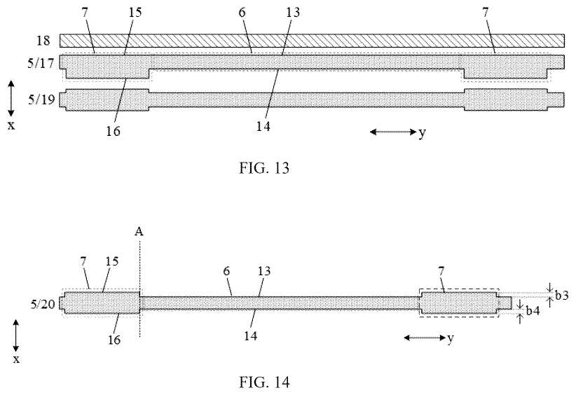

In a feasible implementation, as shown in FIG. 13, which is yet another structural schematic diagram of a first signal line provided by an embodiment of the present disclosure, in the first-type of first signal line 17, the extension line of the third side 15 coincides with the first side 13.

In this arrangement, the second segments 7 of the first-type of first signal line 17 are widened on one side. In this case, the distance between the second segments 7 and the third signal line 18 is kept the same as the distance between the first segments 6 and the third signal line 18, which cannot cause the coupling between the first-type of first signal line 17 and the third signal line 18 to be increased.

In a feasible implementation, as shown in FIG. 14, which is yet another structural schematic diagram of a first signal line provided by an embodiment of the present disclosure, the first segments 6 include a first side 13 and a second side 14 opposite to each other in the first direction x, and the second segments 7 include a third side 15 and a fourth side 16 opposite to each other in the first direction x and both extending in the second direction y.

The first signal lines 5 include a second-type of first signal line 20. In the second-type of first signal line 20, a distance b3 between the first side 13 and an extension line of the third side 15 is equal to a distance b4 between the second side 14 and an extension line of the fourth side 16.

The second segments 7 in the second-type of first signal line 20 have the same widening degree on both sides. This structure is more suitable for the case where the first signal line 5 is far away from other wirings on both sides. Widening the second segments 7 to the same extent on both sides facilitates the second segments 7 to achieve a greater widening proportion, which helps to provide a greater reduction in the load on the second-type of first signal line 20.

The following takes a film layer structure of the pixel circuit 4 as an example to schematically illustrate the second-type of first signal line 20.

As shown in FIG. 15, which is a further schematic diagram of a film layer structure of a display panel provided by an embodiment of the present disclosure, the second-type of first signal line 20 includes the second compensation scanning line PAM-S2. In the second compensation scanning line PAM-S2, the second segments 7 are widened to the same extent on both sides, and thus the second compensation scanning line PAM-S2 can have a lower load. Since the second compensation scanning line PAM-S2 is used to provide a gate signal to the first compensation sub-transistor M11-1, the second compensation sub-transistor M11-2, the second data writing transistor M10, and the anode reset transistor M12 and the number of the driven transistors 8 is larger, the lower the load on the second compensation scanning line PAM-S2 is, the smaller the delay and attenuation degree of a second compensation scanning signal is.

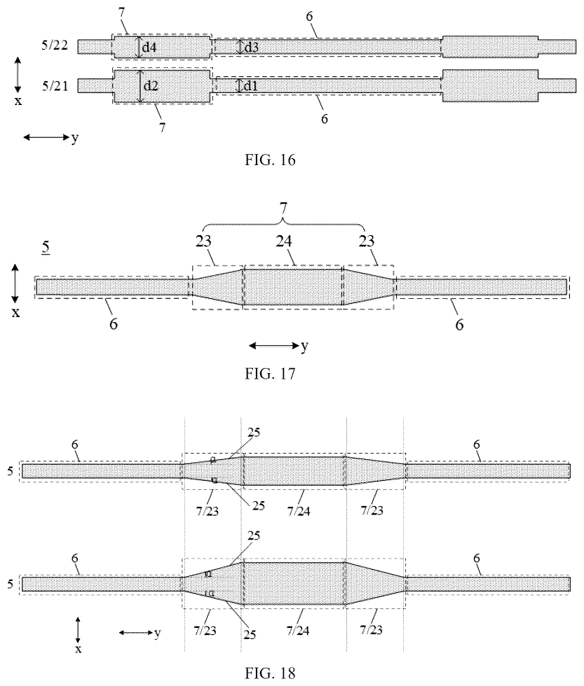

In a feasible implementation, as shown in FIG. 16, which is yet another structural schematic diagram of a first signal line provided by an embodiment of the present disclosure, the first signal line 5 includes a third-type of first signal line 21 and a fourth-type of first signal line 22.

In the third-type of first signal line 21, a line width of the first segments 6 is d1 and a line width of the second segments 7 is d2; and in the fourth-type of first signal line 22, a line width of the first segments 6 is d3 and a line width of the second segments 7 is d4, where d2−d1/d1>d4−d3/d3.

In the display panel, the number of transistors 8 driven by different first signal lines 5 can be different, and the distances between different first signal lines 5 and their adjacent routings can also be different. In the above arrangement, the widening proportions of the second segments 7 in at least two types of first signal lines 5 are designed differently, so that the widening degrees of the second segments 7 in different first signal lines 5 can be better adapted to their own conditions.

For example, at least one of the pixel circuits 4 includes a plurality of transistors 8, and the third-type of first signal line 21 is configured to provide a signal to the gates of some of the plurality of transistors 8. That is, the third-type of first signal line 21 is a scanning line.

Among various types of signal lines electrically connected to the pixel circuits 4, the scanning line is used for controlling the on or off of the transistors 8, and the delay and attenuation of a scanning signal have a more significant influence on the display. Therefore, by setting the third-type of first signal line 21 as a scanning line, the wider second segments 7 in the third-type of first signal line 21 can have a greater improvement effect on the delay and attenuation of the signal.

In contrast, for the fourth-type of first signal line 22, it can be a constant-voltage signal line or a scanning line. For example, the third-type of first signal line 21 includes the second compensation scanning line PAM-S2, and the fourth-type of first signal line 22 includes the second reset scanning line PAM-S1. Compared with the second reset scanning line PAM-S1, the second compensation scanning line PAM-S2 drives a larger number of transistors 8 and is used for controlling the charging and threshold compensation of a second driving transistor M8. Therefore, the second compensation scanning signal has a greater influence on the operation of the pixel circuit 4. Setting the second compensation scanning line PAM-S2 as the third-type of first signal line 21 can have a greater improvement effect on the delay and attenuation of the second compensation scanning signal.

In a feasible implementation, as shown in FIG. 17, which is yet another structural schematic diagram of a first signal line provided by an embodiment of the present disclosure, in at least part of the first signal lines 5, at least one of the second segments 7 includes a third sub-segment 23 and a fourth sub-segment 24, and the third sub-segment 23 is connected between the first segment 6 and the fourth sub-segment 24.

Along a direction from the first segment 6 to the fourth sub-segment 24, a width of the third sub-segment 23 in the first direction x gradually increases, and a maximum width of the third sub-segment 23 in the first direction x is equal to a width of the fourth sub-segment 24 in the first direction x.

The gradual change of the width of the third sub-segment 23 enables the first signal line 5 to have a buffer region for the gradual change of the width when the width of the first signal line 5 changes. Especially when the widening proportion of the second segment 7 is larger, a smooth change in line width and load can be achieved.

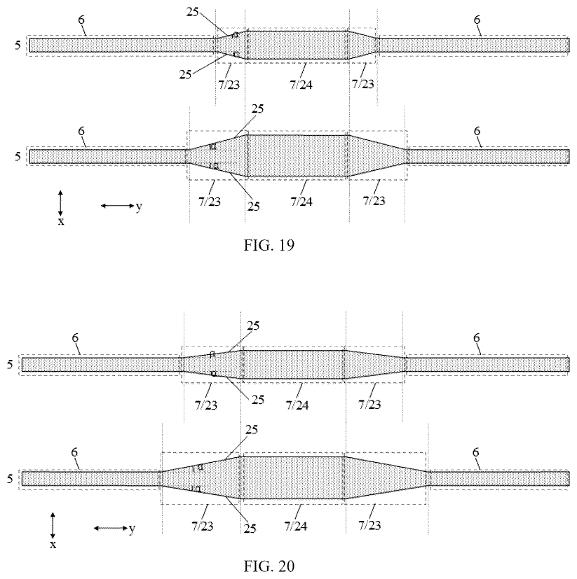

Furthermore, as shown in FIGS. 18 to 20, where FIG. 18 is yet another structural schematic diagram of a first signal line provided by an embodiment of the present disclosure, FIG. 19 is yet another structural schematic diagram of a first signal line provided by an embodiment of the present disclosure, and FIG. 20 is yet another structural schematic diagram of a first signal line provided by an embodiment of the present disclosure, lengths of third sub-segments 23 in the second direction y are different in at least part of the first signal lines 5. And/or, at least one of the third sub-segments 23 includes a fifth side 25, and a first included angle α is provided between the second direction y and an extension direction of the fifth side 25, and the first included angles α corresponding to the third sub-segments 23 are different in at least part of the first signal lines 5.

The above arrangement allows for more flexibility in the design of the third sub-segments 23 in different first signal lines 5. For example, when the widths of the first segments 6 in the first direction x are the same in two types of first signal lines 5, but the widths of the second segments 7 in the first direction x are different, the third sub-segments 23 in the two types of first signal lines can have the same length in the second direction y but different corresponding first included angles α, as shown in FIG. 18; or can have different lengths in the second direction y but the same corresponding first included angle α, as shown in FIG. 19; or can have different lengths in the second direction y and different corresponding first included angles α, as shown in FIG. 20.

In a feasible implementation, as shown in FIGS. 21 and 22, where FIG. 21 is a further schematic diagram of a film layer structure of a display panel provided by an embodiment of the present disclosure, and FIG. 22 is a further schematic diagram of a film layer structure of a display panel provided by an embodiment of the present disclosure, the pixel circuit 4 includes a first pixel circuit 26. The first pixel circuit 26 is adjacent to the interval region 3, and includes at least one first routing 27.

In at least part of the first signal lines 5, in the direction perpendicular to the plane of the display panel, the first segment 6 overlaps the first routing 27, an orthographic projection of the second segment 7 onto the plane of the display panel is adjacent to an orthographic projection of the first routing 27 onto the plane of the display panel, and a distance between the orthographic projection of the second segment 7 onto the plane of the display panel and the orthographic projection of the first routing 27 onto the plane of the display panel is greater than or equal to 1 μm, and further, this distance can be greater than or equal to 1.5 μm.

It should be noted that the fact that the orthographic projection of the second segment 7 onto the plane of the display panel is adjacent to the orthographic projection of the first routing 27 onto the plane of the display panel means that there is no orthographic projection of other longitudinal wiring onto the plane of the display panel between the orthographic projection of the second segment 7 onto the plane of the display panel and the orthographic projection of the first routing 27 onto the plane of the display panel. In other words, the first routing 27 can be understood as a longitudinal routing closest to the second segment 7 in the first pixel circuit 26.

In addition, as shown in FIG. 23, which is a further schematic diagram of a film layer structure of a display panel provided by an embodiment of the present disclosure, the display panel may further include a shielding metal 32. The film layer of the shielding metal 32 is located between the film layer of the transistors 8 closest to the substrate and the substrate. The shielding metal 32 overlaps the channels of the transistor 8 for preventing external ambient light from being irradiated to the channels to affect the device characteristics of the transistors 8. When the orthographic projection of the shielding metal 32 onto the plane of the display panel exists between the orthographic projection of the second segment 7 onto the plane of the display panel and the orthographic projection of the first routing 27 onto the plane of the display panel, this is not the case where there is an orthographic projection of a longitudinal routing between the orthographic projection of the second segment 7 and the orthographic projection of the first routing 27.

When the first signal line 5 is designed to be widened, the distance between an orthographic projection of a widened portion and the orthographic projection of the first routing 27 is made to be at least 1 μm, so that sufficient space can be reserved for the positional deviation between the first routing 27 and the first signal line 5. For example, even if the position of the first routing 27 and/or the position of the first signal line 5 is shifted, it is possible to avoid the second segment 7 and the first routing 27 being too close to each other or overlapping with each other, thereby avoiding an increase in the coupling between the second segment 7 and the first routing 27. Or, when the first routing 27 is an active layer of a certain transistor 8, it is possible to prevent the second segment 7 from overlapping the first routing 27 and thus preventing a change in the width-to-length ratio of the transistor 8.

Further, referring to FIG. 22 again, the first pixel circuit 26 includes a first transistor 28. The first routing 27 includes a first-type of first routing 29, and the first-type of first routing 29 is an active layer of the first transistor 28.

In at least part of the first signal lines 5, a part of the first segment 6 is reused as a gate of the first transistor 28. The orthographic projection of the second segment 7 onto the plane of the display panel is adjacent to an orthographic projection of the first-type of first routing 29 onto the plane of the display panel, and a distance k1 between the orthographic projection of the second segment 7 onto the plane of the display panel and the orthographic projection of the first-type of first routing 29 onto the plane of the display panel is greater than or equal to 1 μm.

For example, the first transistor 28 is the anode reset transistor M12, and the first-type of first routing 29 is an active layer of the anode reset transistor M12. The first signal lines 5 include the second compensation scanning line PAM-S2. In the second compensation scanning line PAM-S2, a part of the first segment 6 is reused as the gate of the anode reset transistor M12, and a distance between the orthographic projection of the second segment 7 onto the plane of the display panel and the orthographic projection of the active layer of the anode reset transistor M12 onto the plane of the display panel is k1.

When the first-type of first routing 29 is the active layer of the first transistor 28, the orthographic projection of the active layer is spaced from the orthographic projection of the second segment 7 by more than 1 μm, which leaves sufficient margin for the routing offset caused by the process error, and can prevent the second segment 7 from overlapping the active layer and affecting the width-to-length ratio of the channel of the first transistor 28.

And/or, referring to FIG. 22 again, the first pixel circuit 26 includes a second transistor 30. The first routing 27 includes a second-type of first routing 31, and the second-type of first routing 31 is electrically connected to the second transistor 30.

In at least part of the first signal lines 5, in the direction perpendicular to the plane of the display panel, the first segment 6 overlaps the second-type of first routing 31. The orthographic projection of the second segment 7 onto the plane of the display panel is adjacent to an orthographic projection of the second-type of first routing 31 onto the plane of the display panel, and a distance k2 between the orthographic projection of the second segment 7 onto the plane of the display panel and the orthographic projection of the second-type of first routing 31 onto the plane of the display panel is greater than or equal to 1 μm.

The second transistor 30 and the above-mentioned first transistor 28 may be the same transistor 8 or different transistors 8.

For example, referring to FIG. 22, the second transistor 30 is also the anode reset transistor M12, and the second-type of first routing 31 is a connection line between the anode reset transistor M12 and the anode reset line PAM-INIT. The first signal lines 5 include the second reset scanning line PAM-S1. In the second reset scanning line PAM-S1, the orthographic projection of the first segment 6 onto the plane of the display panel overlaps an orthographic projection of the connection line between the anode reset transistor M12 and the anode reset line PAM-INIT onto the plane of the display panel, and a distance between the orthographic projection of the second segment 7 onto the plane of the display panel and the orthographic projection of the connection line onto the plane of the display panel is k2.

When the second-type of first routing 31 is a connection line between the second transistor 30 and another structure, an orthographic projection of the connection line is spaced from the orthographic projection of the second segment 7 by more than 1 μm, which reserves sufficient margin for the routing offset caused by the process error, and can prevent the second segment 7 and the connection line from being too close to each other or overlapping with each other and thus increasing the coupling between the connection line and the second segment 7.

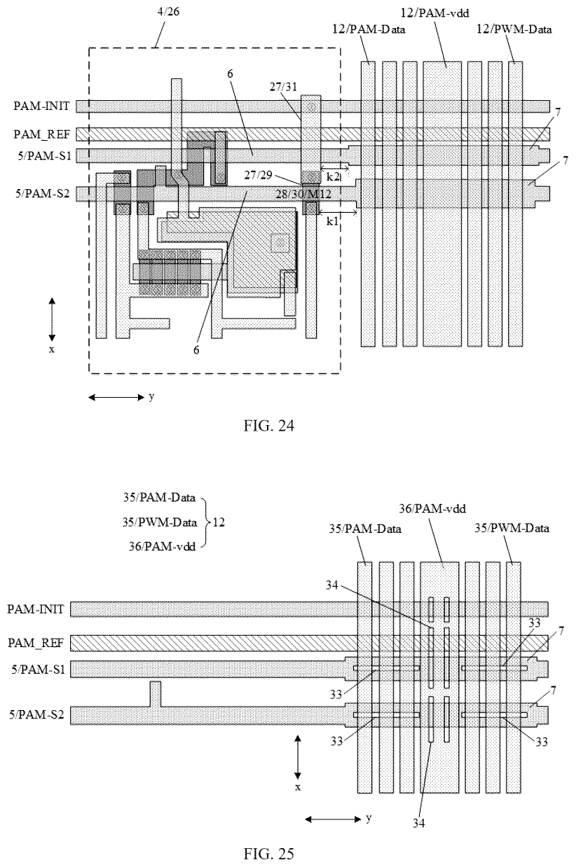

In a feasible implementation, as shown in FIG. 24, which is a further schematic diagram of a film layer structure of a display panel provided by an embodiment of the present disclosure, in at least part of the first signal lines 5, the widths of the second segments 7 in the first direction x are different, and the distances between the orthographic projections of the second segments 7 onto the plane of the display panel and the orthographic projection of the first routing 27 onto the plane of the display panel are also different.

For example, referring to FIG. 24, the first signal lines 5 include the second reset scanning line PAM-S1 and the second compensation scanning line PAM-S2. The width of the second segment 7 in the second compensation scanning line PAM-S2 in the first direction x is greater than the width of the second segment 7 in the second reset scanning line PAM-S1 in the first direction x. The distance between the orthographic projection of the second segment 7 in the second compensation scanning line PAM-S2 onto the plane of the display panel and the orthographic projection of the first-type of first routing 29 onto the plane of the display panel is greater than the distance between the orthographic projection of the second segment 7 in the second reset scanning line PAM-S1 onto the plane of the display panel and the orthographic projection of the second-type of first routing 31 onto the plane of the display panel.

The second compensation scanning line PAM-S2 is used for controlling the charging and threshold compensation of the second driving transistor M8, and the quality of the second compensation scanning signal has a greater influence on the pixel circuit 4. Therefore, the widening proportion of the second segment 7 in the second compensation scanning line PAM-S2 can be set larger. Meanwhile, in the second compensation scanning line PAM-S2, the first routing 28 adjacent to the second segment 7 is the active layer of the anode reset transistor M12. Since the width of the second segment 7 is larger, if the active layer of the anode reset transistor M12 overlaps the second segment 7 due to the routing position offset, the width-to-length ratio of the channel of the anode reset transistor M12 may be changed significantly. Therefore, the distance between the orthographic projection of the second segment 7 in the second compensation scanning line PAM-S2 and the orthographic projection of the first-type of first routing 29 can also be set larger to avoid this problem.

Further, the width of the second segment 7 in the first direction x is positively correlated with the distance between the orthographic projection of the second segment 7 onto the plane of the display panel and the orthographic projection of the first routing 27 onto the plane of the display panel. That is, for different first signal lines 5, the greater the width of the second segment 7 in the first direction x in a first signal line 5 is, the greater the distance between the orthographic projection of its second segment 7 and the orthographic projection of the first routing 27 is.

In a feasible implementation, as shown in FIG. 25, which is yet another structural schematic diagram of a display panel provided by an embodiment of the present disclosure, the display panel further includes second signal lines 12 extending in the first direction x and located in the interval regions 3.

In at least part of the first signal lines 5, the second segments 7 include first hollows 33, and in the direction perpendicular to the plane of the display panel, the first hollows 33 overlap the second signal lines 12. And/or, at least part of the second signal lines 12 include second hollows 34, and in the direction perpendicular to the plane of the display panel, the second hollows 34 overlap the second segments 7.

When the first signal lines 5 extend horizontally, they inevitably overlap the second signal lines 12 extending longitudinally. In the embodiments of the present disclosure, by providing the first hollows 33 on the second segments 7 of at least part of the first signal lines 5 and/or providing the second hollows 34 on at least part of the second signal lines 12, the overlapping area between the first signal lines 5 and the second signal lines 12 in the interval regions 3 can be reduced, thereby reducing the coupling therebetween and reducing signal interference.

In a feasible implementation, referring to FIG. 25 again, the second signal lines 12 include a first-type of second signal line 35 and a second-type of second signal line 36.

The first-type of second signal line 35 is used to transmit a variable-voltage signal. The variable-voltage signal refers to a signal whose voltage changes, for example, it may include a data signal, etc. The second-type of second signal line 36 is used to transmit a constant-voltage signal. The constant-voltage signal refers to a signal whose voltage does not change, for example, it may include a power supply signal, a reset signal, etc.

In the direction perpendicular to the plane of the display panel, the first hollows 33 overlap the first-type of second signal line 35, and the second-type of second signal line 36 includes the second hollows 34.

Under normal circumstances, the second-type of second signal line 36 used to transmit the constant-voltage signal in the interval region 3 may have a larger line width. With the above structure, on one hand, the first hollows 33 in the first signal line 5 overlap the first-type of second signal line 35, and the first hollows 33 can be used to reduce the coupling between the first signal lines 5 and the first-type of second signal line 35. In this way, the first-type of second signal line 35 does not need to be provided with the second hollow 34, avoiding affecting the routing resistance of the first-type of second signal line 35 itself. On the other hand, the second-type of second signal line 36 is provided with the second hollows 34, and the second hollows 34 can be used to reduce the coupling between the first signal lines 5 and the second-type of second signal line 36. In this way, the first signal lines 5 do not need to be provided with the first hollows 33 at the positions where they overlap the second-type of second signal line 36, avoiding the influence on the resistance of the first signal lines 5 themselves due to too many hollows in the first signal lines 5.

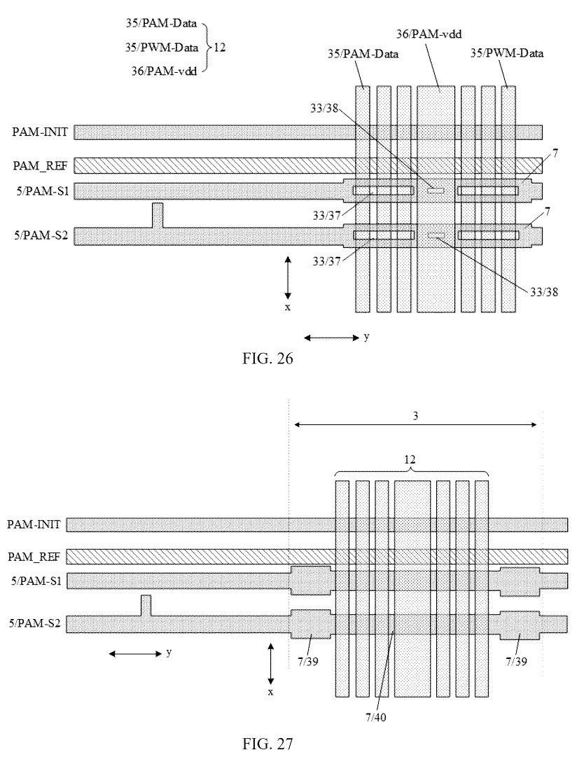

In a feasible implementation, as shown in FIG. 26, which is yet another structural schematic diagram of a display panel provided by an embodiment of the present disclosure, the second signal lines 12 include a first-type of second signal line 35 and a second-type of second signal line 36.

The first-type of second signal line 35 is used to transmit a variable-voltage signal. The variable-voltage signal refers to a signal whose voltage changes, for example, it may include a data signal, etc. The second-type of second signal line 36 is used to transmit a constant-voltage signal. The constant-voltage signal refers to a signal whose voltage does not change, for example, it may include a power supply signal, a reset signal, etc.

The first hollows 33 includes a first sub-hollow 37 and a second sub-hollow 38, and an area of the first sub-hollow 37 is larger than an area of the second sub-hollow 38. In the direction perpendicular to the plane of the display panel, the first sub-hollow 37 overlaps the first-type of second signal line 35, and the second sub-hollow 38 overlaps the second-type of second signal line 36.

Compared with the constant-voltage signal, the variable-voltage signal is more likely to cause signal instability due to coupling and other reasons. Therefore, when providing hollows on the second segments 7 of the first signal lines 5, some hollows with a larger area can be designed to overlap the first-type of second signal line 35 to reduce the coupling between the first signal lines 5 and the first-type of second signal line 35 to a greater extent, thereby reducing the signal interference therebetween to improve the stability of the variable-voltage signal on the first-type of second signal line 35.

Further, referring to FIGS. 25 and 26, the first-type of second signal line 35 includes a data line for providing a data voltage to the pixel circuits 4. For example, in conjunction with FIGS. 32 to 34, when the pixel circuit 4 includes a pulse width modulation module PWM and a pulse amplitude modulation module PAM, the first-type of second signal line 35 may include a first data line PWM-Data electrically connected to the pulse width modulation module PWM and a second data line PAM-Data electrically connected to the pulse amplitude modulation module PAM.

The second-type of second signal line 36 includes a power line for providing a power voltage to the pixel circuits 4, and/or includes a reset line for providing a reset voltage to the pixel circuits 4. For example, in conjunction with FIGS. 32 to 34, when the pixel circuit 4 includes the pulse width modulation module PWM and the pulse amplitude modulation module PAM, the second-type of second signal line 36 may include at least one of the first reset line PWM-REF and the first power line PWM-vdd electrically connected to the pulse width modulation module PWM, and/or includes at least one of the second reset line PAM-REF, the anode reset line PAM-INIT, and the second power line PAM-vdd electrically connected to the pulse amplitude modulation module PAM.

In a feasible implementation, as shown in FIG. 27, which is yet another structural schematic diagram of a display panel provided by an embodiment of the present disclosure, the display panel further includes second signal lines 12 extending in the first direction x and located in the interval regions 3.

In at least part of the first signal lines 5, at least one of the second segments 7 includes a fifth sub-segment 39 and a sixth sub-segment 40. In the direction perpendicular to the plane of the display panel, the fifth sub-segment 39 does not overlap the second signal lines 12, the sixth sub-segment 40 overlaps the second signal lines 12, and a width of the fifth sub-segment 39 in the first direction x is greater than a width of the sixth sub-segment 40 in the first direction x.

In this structure, the second segment 7 includes the fifth sub-segment 39 and the sixth sub-segment 40 with different widths. By making the fifth sub-segment 39 having a larger width not overlap with the second signal lines 12, it is possible to avoid the second segment 7 having a large coupling with the second signal line 12 while utilizing the fifth sub-segment 39 to reduce the load on the first signal line 5 to a greater extent.

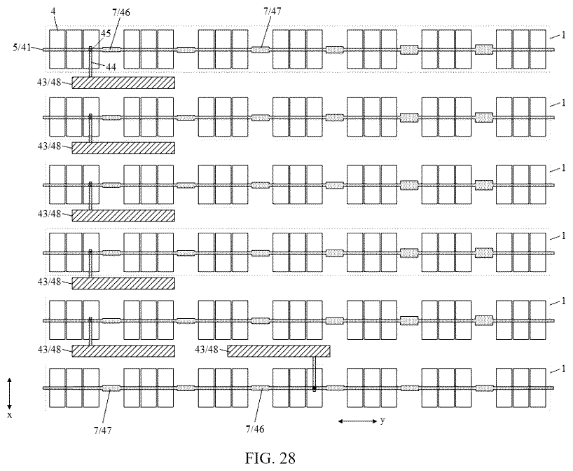

In a feasible implementation, referring to FIGS. 28 to 30, the first signal lines 5 include a fifth-type of first signal line 41. In the fifth-type of first signal line 41, the widths of at least part of the second segments 7 in the first direction x are different, so that different widths of the second segments 7 are utilized at different positions for different degrees of reduction of the load, so as to better adapt to the signal attenuation of the fifth-type of first signal line 41 at different positions, etc.

In a feasible implementation, as shown in FIG. 28, which is yet another structural schematic diagram of a display panel provided by an embodiment of the present disclosure, the display panel further includes first shift registers 43. A first connection line 44 is connected between the fifth-type of first signal line 41 and one first shift register 43, and a first via hole 45 is provided between the fifth-type of first signal line 41 and the first connection line 44.

The second segments 7 in the fifth-type of first signal line 41 includes a first-type of second segment 46 and a second-type of second segment 47. A distance between the second-type of second segment 47 and the first via hole 45 is greater than a distance between the first-type of second segment 46 and the first via hole 45, and a width of the second-type of second segment 47 in the first direction x is greater than a width of the first-type of second segment 46 in the first direction X.

In the embodiments of the present disclosure, the first shift registers 43 may be located in a display region. At least one of the first shift registers 43 includes a plurality of first shift units 48 that are cascaded, and the first shift units 48 are electrically connected to the fifth-type of first signal line 41 through the first connection line 44. The first shift units 48 can be arranged between adjacent circuit rows 1, thereby avoiding occupying the bezel space, so as to enable the display panel to achieve a bezel-less design.

In the fifth-type of first signal line 41, for the second-type of second segment 47 that is far away from the first via hole 45, since a transmission distance of a signal output by the first shift units 48 is longer, the degree of delay and attenuation of the signal during transmission will be greater. By making the second-type of second segment 47 have a larger line width, the larger line width can be used to weaken the problems of large delay and attenuation caused by the longer signal transmission distance at this position, thereby helping to optimize the signal consistency at different positions in the fifth type of first signal line 41.

In a feasible implementation, referring to FIGS. 28 to 30 again, in the fifth-type of first signal line 41, at least three second segments 7 continuously arranged have a gradual change in width in the first direction x, so as to achieve a smooth change in load on the fifth-type of first signal line 41 in different regions.

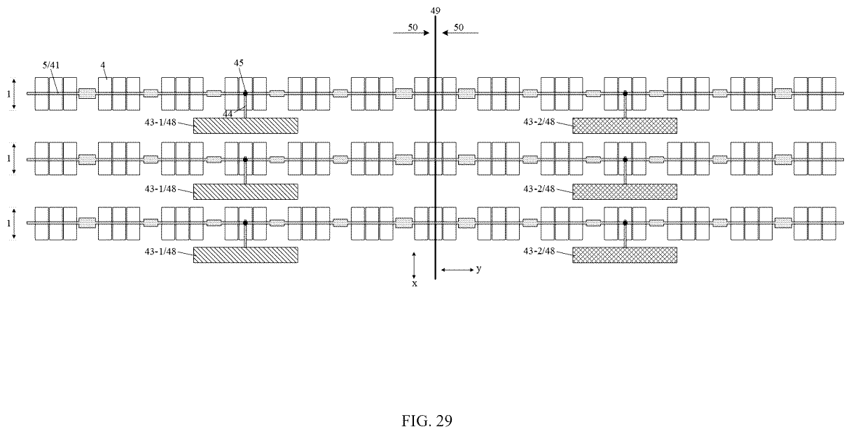

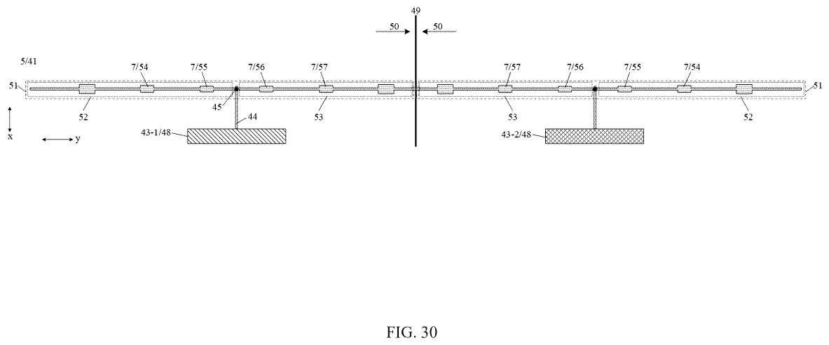

In a feasible implementation, as shown in FIGS. 29 and 30, where FIG. 29 is yet another structural schematic diagram of a display panel provided by an embodiment of the present disclosure, and FIG. 30 is a structural schematic diagram of a first signal line 5 corresponding to FIG. 29, the display panel has a first central axis 49 extending in the first direction x, and the display panel includes two first display regions 50 located on opposite sides of the first central axis 49.

The display panel includes first shift registers 43. At least one of the first shift registers 43 includes a plurality of first shift units 48 that are cascaded, and the first shift units 48 are located between adjacent circuit rows 1. The fifth-type of first signal line 41 is electrically connected to two first shift registers 43, and the two first shift registers 43 are respectively located in the two first display regions 50.

To facilitate differentiation, in FIGS. 29 and 30, the two first shift registers 43 are identified by reference signs 43-1 and 43-2, respectively.

Referring to FIG. 30, the fifth-type of first signal line 41 includes two first parts 51, the two first parts 51 are respectively located in the two first display regions 50. Each of the two first parts 51 includes a first sub-part 52 and a second sub-part 53, and the second sub-part 53 of one of the two first parts 51 is connected between the first sub-part 52 of the one of the two first parts 51 and the other one of the other first part 51.

The second segments 7 in the first sub-part 52 include a third-type of second segment 54 and a fourth-type of second segment 55. A distance between the third-type of second segment 54 and the first central axis 49 is greater than a distance between the fourth-type of second segment 55 and the first central axis 49, and a width of the third-type of second segment 54 in the first direction x is greater than a width of the fourth-type of second segment 55 in the first direction x.

The second segments 7 in the second sub-part 53 includes a fifth-type of second segment 56 and a sixth-type of second segment 57. A distance between the fifth-type of second segment 56 and the first central axis 49 is greater than a distance between the sixth-type of second segment 57 and the first central axis 49, and a width of the fifth-type of second segment 56 in the first direction x is less than a width of the sixth-type of second segment 57 in the first direction x.

More specifically, in the first display region 50, a first connection line 44 is connected between the first shift units 48 and the first signal line 5, and the first connection line 44 is connected to the first signal line 5 through a first via hole 45. The first part 51 can be divided into the first sub-part 52 and the second sub-part 53 according to the position of the first via hole 45. That is, the first sub-part 52 is located on one side of the first via hole 45 away from the first central axis 49, and the second sub-part 53 is located on one side of the first via hole 45 close to the first central axis 49.

In the first sub-part 52, along a direction pointing to the first central axis 49, the widths of multiple second segments 7 in the first direction x can be set to decrease; in the second sub-part 53, along the direction pointing to the first central axis 49, the widths of multiple second segments 7 in the first direction x can be set to increase.

In this structure, the two first shift registers 43 perform bilateral driving on the first signal line 5. When one first shift register 43 is provided in each of the two first display regions 50, the second segments 7 at different positions of the first part 51 can be designed with finer width variations according to the connection position of the first shift register 43 with the first part 51 of the first signal line 5, so that the second line segments 7 at positions with a longer signal transmission distance have a larger width, which helps to optimize the signal uniformity of the first signal line 5 at different positions.

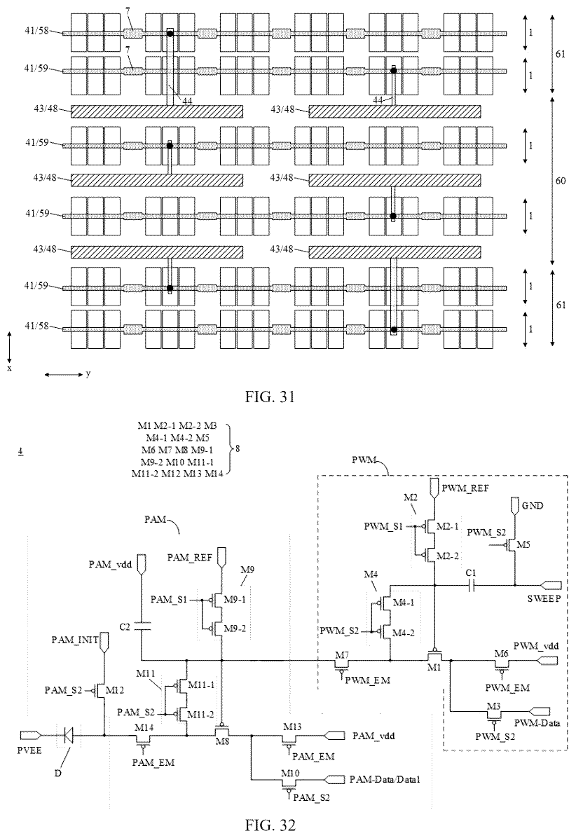

In a feasible implementation, as shown in FIG. 31, which is yet another structural schematic diagram of a display panel provided by an embodiment of the present disclosure, the display panel further includes first shift registers 43. At least one of the first shift registers 43 includes a plurality of first shift units 48 that are cascaded, and the first shift units 48 are located between adjacent circuit rows 1.

The first signal lines 5 include a fifth-type of first signal line 41, and the fifth-type of first signal line 41 is electrically connected to the first shift units 48.

The fifth-type of first signal line 41 include a first signal sub-line 58 and a second signal sub-line 59. A distance between the first signal sub-line 58 and the first shift units 48 connected thereto in the first direction x is greater than a distance between the second signal sub-line 59 and the first shift unit 48 connected thereto in the first direction x, and a width of the second segments 7 in the first signal sub-line 58 in the first direction x is greater than a width of the second segments 7 in the second signal sub-line 59 in the first direction x.

In a bezel-less display panel, the pixel circuits 4 at the edge positions usually adopt a retracted design. For example, referring to FIG. 31, the display panel includes a first sub-region 60 and two second sub-regions 61 arranged in the first direction x, and the two second sub-regions 61 are located on opposite sides of the first sub-region 60. A distance between adjacent circuit rows 1 in each of the second sub-regions 61 is less than a distance between adjacent circuit rows 1 in the first sub-region 60. When the first shift units 48 are located between adjacent circuit rows 1, the first shift units 48 are generally disposed on one side of the circuit row 1 in the first sub-region 60. In this structure, the above-mentioned first signal sub-line 58 at least includes the fifth-type of first signal line 41 in the second sub-region 61, and the second signal sub-line 59 at least includes the fifth-type of first signal line 41 in the first sub-region 60.

For the first shift units 48 and the first signal sub-line 58 that are electrically connected to each other, the signal output by the first shift units 48 needs to transmit a longer distance to reach the first signal sub-line 58. Therefore, the embodiment of the present disclosure proposes that the width of the second segments 7 in the first signal sub-line 58 can be set larger, so that the larger line width can be used to weaken the problems of larger delay and attenuation of the first signal sub-line 58 caused by the longer signal transmission distance, which helps to improve the signal consistency between the first signal sub-line 58 and the second signal sub-line 59.

Further, referring to FIG. 31 again, a first connection line 44 is connected between the fifth-type of first signal line 41 and the first shift units 48. A line width of the first connection line 44 connected to the first signal sub-line 58 is greater than a line width of the first connection line 44 connected to the second signal sub-line 59, so that the first connection lines 44 are used to further alleviate the problems of signal delay and attenuation of the first signal sub-line 58.

In a feasible implementation, at least one of the pixel circuits 4 includes a plurality of transistors 8, and at least part of the first signal lines 5 are used to provide signals to the gates of the transistors 8. That is, the first signal lines 5 include scanning lines. The scanning lines are used to drive the transistors 8 to turn on and off, and the signal quality of the scanning lines has a greater influence on the operation of the pixel circuit 4. Therefore, after the scanning lines are designed to be widened to improve the delay and attenuation of the scanning signals, the display effect can be better improved.

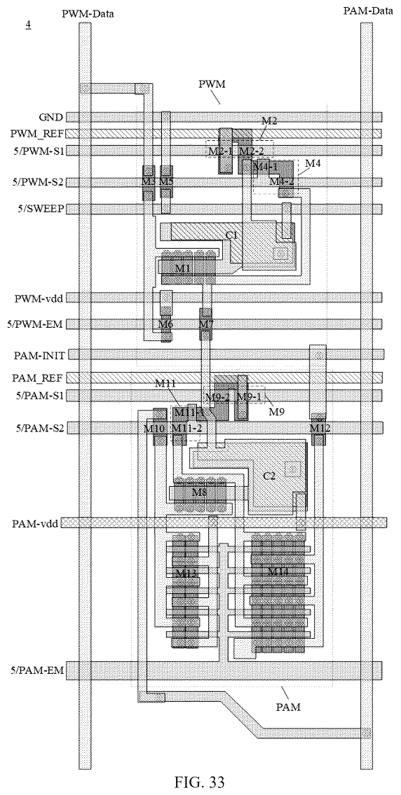

In a feasible implementation, as shown in FIGS. 32 and 33, where FIG. 32 is a schematic diagram of a circuit structure of a pixel circuit provided by an embodiment of the present disclosure, and FIG. 33 is a schematic diagram of a film layer structure of a pixel circuit provided by an embodiment of the present disclosure, the pixel circuit 4 includes a pulse width modulation module PWM and a pulse amplitude modulation module PAM. The pulse width modulation module PWM realizes different brightness display by controlling the light-emitting time, and the pulse amplitude modulation module PAM realizes different brightness display by controlling the magnitude of the light-emitting current.

This type of pixel circuit 4 is more suitable for a bezel-less splicing display screen. In this type of display screen, the PPI (Pixels Per Inch) of the display panel is smaller, and this type of pixel circuit 4 can enable a light-emitting element to maintain higher light-emitting efficiency. However, this type of pixel circuit 4 has a complex structure and is affected by factors such as parasitic capacitance, and thus a signal line connected to this type of pixel circuit 4 usually has a large load. By adopting the technical solutions of widening the first signal line 5 provided by the embodiments of the present disclosure, the problem of a larger load on the signal line can be effectively overcome.

The pulse width modulation module PWM includes: a first driving transistor M1, a first gate reset transistor M2, a first data writing transistor M3, a first threshold compensation transistor M4, a first capacitor C1, a control transistor M5, a first light-emitting control transistor M6, and a second light-emitting control transistor M7.

The first gate reset transistor M2 is electrically connected between the first reset line PWM-REF and a gate of the first driving transistor M1.

In one case, the first gate reset transistor M2 is a dual-gate transistor, including a third reset sub-transistor M2-1 and a fourth reset sub-transistor M2-2 connected in series. A gate of the third reset sub-transistor M2-1 and a gate of the fourth reset sub-transistor M2-2 are electrically connected to each other. A first electrode of the third reset sub-transistor M2-1 is electrically connected to the first reset line PAWM-REF, and a second electrode of the fourth reset sub-transistor M2-2 is electrically connected to the gate of the first driving transistor M1.

The first data writing transistor M3 is electrically connected between the first data line PWM-Data and a first electrode of the first driving transistor M1.

The first threshold compensation transistor M4 is electrically connected between a second electrode of the first driving transistor M1 and the gate of the first driving transistor M1.

In one case, the first threshold compensation transistor M4 is a dual-gate transistor, including a third compensation sub-transistor M4-1 and a fourth compensation sub-transistor M4-2 connected in series. A gate of the third compensation sub-transistor M4-1 and a gate of the second compensation sub-transistor M4-2 are electrically connected to each other. A first electrode of the third compensation sub-transistor M4-1 is electrically connected to the second electrode of the first driving transistor M1, and a second electrode of the fourth compensation sub-transistor M4-2 is electrically connected to the gate of the first driving transistor M1.

The first capacitor C1 is electrically connected between a frequency-sweep line SWEEP and the gate of the first driving transistor M1.

A first electrode of the control transistor M5 is electrically connected to a ground line GND, and a second electrode of the control transistor M5 is electrically connected to the gate of the first driving transistor M1 through the first capacitor C1.

The first light-emitting control transistor M6 is electrically connected between the first power line PWM-vdd and the first electrode of the first driving transistor M1.

The second light-emitting control transistor M7 is electrically connected between the second electrode of the first driving transistor M1 and the pulse amplitude modulation module PAM.

The pulse amplitude modulation module PAM includes: a second driving transistor M8, a second gate reset transistor M9, a second data writing transistor M10, a second compensation transistor M11, an anode reset transistor M12, a third light-emitting control transistor M13, a fourth light-emitting control transistor M14, and a second capacitor C2.

A gate of the second driving transistor M8 is electrically connected to a second electrode of the second light-emitting control transistor M7.

The second gate reset transistor M9 is electrically connected between the second reset line PAM-REF and the gate of the second driving transistor M8.

In one case, the second gate reset transistor M9 is a dual-gate transistor, including a first reset sub-transistor M9-1 and a second reset sub-transistor M9-2 connected in series. A gate of the first reset sub-transistor M9-1 and a gate of the second reset sub-transistor M9-2 are electrically connected to each other. A first electrode of the first reset sub-transistor M9-1 is electrically connected to the second reset line PAM-REF, and a second electrode of the second reset sub-transistor M9-2 is electrically connected to the gate of the second driving transistor M8.

The second data writing transistor M10 is electrically connected to a first electrode of the second driving transistor M8 and the second data line PAM-Data.

The second compensation transistor M11 is electrically connected between a second electrode of the second driving transistor M8 and the gate of the second driving transistor M8.

In one case, the second compensation transistor M11 is a dual-gate transistor, including a first compensation sub-transistor M11-1 and a second compensation sub-transistor M11-2 connected in series. A gate of the first compensation sub-transistor M11-1 and a gate of the second compensation sub-transistor M11-2 are electrically connected to each other. A first electrode of the second compensation sub-transistor M11-2 is electrically connected to the second electrode of the second driving transistor M8, and a second electrode of the first compensation sub-transistor M11-1 is electrically connected to the gate of the second driving transistor M8.

The anode reset transistor M12 is electrically connected between the anode reset line PAM-INIT and a light-emitting element D.

The third light-emitting control transistor M13 is electrically connected between the second power line PAM-vdd and the first electrode of the second driving transistor M8.

The fourth light-emitting control transistor M14 is electrically connected between the second electrode of the second driving transistor M8 and the light-emitting element D.

The second capacitor C2 is electrically connected between the second power line PAM-vdd and the gate of the second driving transistor M8.

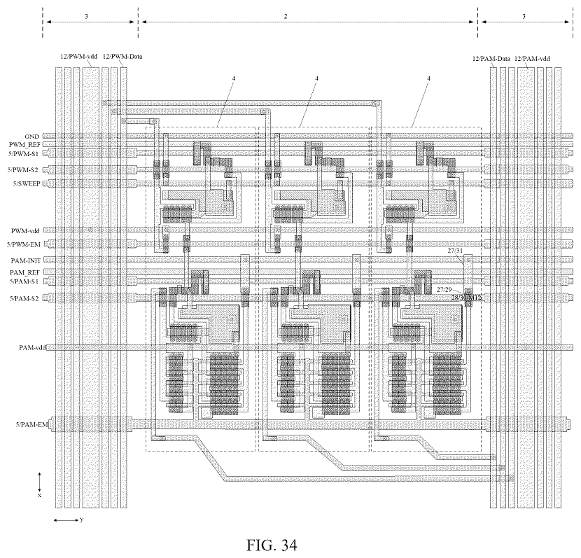

In the embodiments of the present disclosure, as shown in FIG. 34, which is a further schematic diagram of a film layer structure of a display panel provided by an embodiment of the present disclosure, the first signal lines 5 may include.
a first reset scanning line PWM-S1 for providing a signal to a gate of the first gate reset transistor M2, so as to improve the delay and attenuation of a first reset scanning signal, etc.; and/or
a first compensation scanning line PWM-S2 for providing a signal to a gate of the first threshold compensation transistor M4, a gate of the first data writing transistor M3, and a gate of the control transistor M5, so as to improve the delay and attenuation of a first compensation scanning signal, etc.; and/or
a first light-emitting control scanning line PWM-EM for providing a signal to a gate of the first light-emitting control transistor M6 and a gate of the second light-emitting control transistor M7, so as to reduce the load on the first light-emitting control scanning line PWM-EM and improve the delay and attenuation of a first light-emitting control scanning signal, etc.; and/or
a second reset scanning line PAM-S1 for providing a signal to a gate of the second gate reset transistor M9, so as to improve the delay and attenuation of a second reset scanning signal, etc.; and/or
a second compensation scanning line PAM-S2 for providing a signal to a gate of the second data writing transistor M10, a gate of the second threshold compensation transistor M11, and a gate of the anode reset transistor M12, so as to improve the delay and attenuation of a second compensation scanning signal, etc.; and/or
a second light-emitting control scanning line PAM-EM for providing a signal to a gate of the third light-emitting control transistor M13 and a gate of the fourth light-emitting control transistor M14, so as to improve the delay and attenuation of a second light-emitting control scanning signal, etc.

The first reset scanning line PWM-S1 and the first compensation scanning line PWM-S2 are respectively used for controlling the gate reset, charging, and threshold compensation of the first driving transistor M3, and the second reset scanning line PAM-S1 and the second compensation scanning line PAM-S2 are respectively used for controlling the gate reset, charging, and threshold compensation of the second driving transistor M8. These four scanning lines have a greater influence on the performance of the pixel circuit 4, and correspondingly have a greater influence on the display effect.

Therefore, in the embodiments of the present disclosure, the first signal lines 5 may include at least one or more of the first reset scanning line PWM-S1, the first compensation scanning line PWM-S2, the second reset scanning line PAM-S1, and the second compensation scanning line PAM-S2.

In a feasible implementation, referring to FIGS. 32 to 34, the pixel circuit 4 includes a pulse width modulation module PWM, and the pulse width modulation module PWM includes a first driving transistor M1 and a first capacitor C1.

The first signal lines 5 include the frequency-sweep line SWEEP, and the frequency-sweep line SWEEP is electrically connected to the gate of the first driving transistor M1 through the first capacitor C1.

A frequency-sweep signal can help to more accurately determine the duty cycle of the light-emitting time of each pixel and present accurate dark details. Making the first signal lines 5 include the frequency-sweep line SWEEP can improve the delay and attenuation of the frequency-sweep signal, etc., and in turn also help to optimize the display effect.

In addition, it should be noted that the circuit structure of the pixel circuit 4 shown in the drawings of the embodiments of the present disclosure and the arrangement of the transistors 8 in the layout of the pixel circuit 4 are only for illustrative purposes. In other alternative embodiments of the present disclosure, the pixel circuit 4 may also adopt other circuit structures, or the transistors 8 in the layout may also adopt other arrangements.

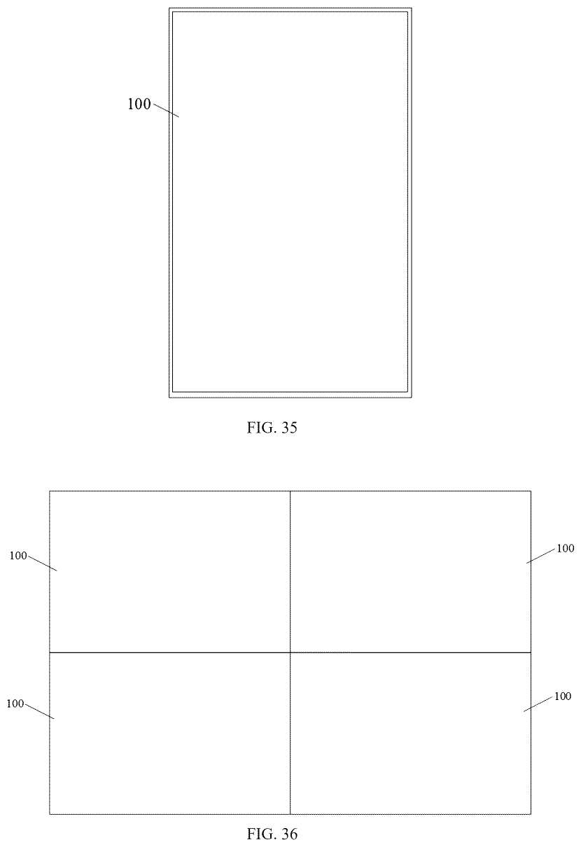

Based on the same inventive concept, an embodiments of the present disclosure further provides a display apparatus. As shown in FIGS. 35 and 36, where FIG. 35 is a structural schematic diagram of a display apparatus provided by an embodiment of the present disclosure, and FIG. 36 is another structural schematic diagram of a display apparatus provided by an embodiment of the present disclosure, the display apparatus includes the above-mentioned display panel 100.

It should be noted that the display apparatuses shown in FIGS. 35 and 36 are only for illustrative purposes. In the embodiments of the present disclosure, the display apparatus may be an electronic device such as a mobile phone or a computer illustrated in FIG. 35, or a splicing display screen including at least two display panels 100 illustrated in FIG. 36, etc.

The above descriptions are only preferred embodiments of the present disclosure and are not intended to limit the present disclosure. Any modifications, equivalent replacements, improvements, etc. made within the spirit and principle of the present disclosure should be included within the protection scope of the present disclosure.

Finally, it should be noted that the above embodiments are only used to illustrate the technical solutions of the present disclosure, rather than to limit them. Although the present disclosure has been described in detail in conjunction with the above embodiments, those of skill in the art should understand that they can still modify the technical solutions described in the above embodiments, or equivalently replace some or all of the technical features, and such modifications or replacements should not make the essence of the corresponding technical solutions deviate from the scope of the technical solutions of the various embodiments of the present disclosure.

What is claimed is:

1. A display panel, comprising:
a plurality of circuit rows arranged in a first direction, wherein at least one circuit row of the plurality of circuit rows comprises circuit regions and interval regions alternately arranged in a second direction, the circuit regions comprise pixel circuits, and the first direction intersects the second direction; and
first signal lines extending in the second direction and electrically connected to the pixel circuits, wherein at least one of the first signal lines comprises first segments, at least one of which is located in one circuit region, and second segments, at least one of which is at least located in one interval region, and a width of at least part of the second segments in the first direction is greater than a width of at least part of the first segments in the first direction.

2. The display panel according to claim 1, wherein
at least one of the pixel circuits comprises a plurality of transistors; and
in at least part of the first signal lines, at least one of the first segments comprises a first sub-segment and a second sub-segment that are connected to each other, the first sub-segment is reused as a gate of a transistor of the plurality of transistors, a channel length direction corresponding to the gate that the first sub-segment is reused as is the first direction, and a width of the second segments in the first direction is greater than a width of the first sub-segment in the first direction.

3. The display panel according to claim 1, further comprising second signal lines extending in the first direction and located in the interval regions,
wherein in at least part of the first signal lines, a junction of one second segment of the second segments and one first segment of the first segments is located in one interval region of the interval regions, and a distance between the junction and one pixel circuit of the pixel circuits that is adjacent thereto is less than a distance between the junction and one second signal line of the second signal lines that is adjacent thereto.

4. The display panel according to claim 1, wherein
at least one of the first segments comprises a first side and a second side opposite to each other in the first direction, and at least one of the second segments comprises a third side and a fourth side opposite to each other in the first direction and both extending in the second direction; and
the first signal lines comprise a first-type of first signal line, and in the first-type of first signal line, a distance between the first side and an extension line of the third side is less than a distance between the second side and an extension line of the fourth side.

5. The display panel according to claim 4,
further comprising a third signal line and a fourth signal line, wherein the third signal line extends in the second direction and is adjacent to the first-type of first signal line on one side of the first side, the fourth signal line extends in the second direction and is adjacent to the first-type of first signal line on one side of the second side, and a distance between the third signal line and the first side is less than a distance between the fourth signal line and the second side; or
further comprising a third signal line extending in the second direction and adjacent to the first-type of first signal line on one side of the first side, wherein the third signal line and the first-type of first signal line are disposed in different layers; or
wherein in the first-type of first signal line, the extension line of the third side coincides with the first side.

6. The display panel according to claim 1, wherein
the first signal lines comprise a third-type of first signal line and a fourth-type of first signal line;
in the third-type of first signal line, a line width of the first segments is d1 and a line width of the second segments is d2; and in the fourth-type of first signal line, a line width of the first segments is d3 and a line width of the second segments is d4, where
$$\frac{d 2 - d 1}{d 1} > \frac{d 4 - d 3}{d 3} .$$

7. The display panel according to claim 1, wherein
in at least part of the first signal lines, at least one of the second segments comprises a third sub-segment and a fourth sub-segment, and the third sub-segment is connected between one of the first segments and the fourth sub-segment; and
along a direction from the one of the first segments to the fourth sub-segment, a width of the third sub-segment in the first direction gradually increases, and a maximum width of the third sub-segment in the first direction is equal to a width of the fourth sub-segment in the first direction.

8. The display panel according to claim 7, wherein
in the at least part of the first signal lines, lengths of third sub-segments in the second direction are different; and/or
at least one of the third sub-segments comprises a fifth side, a first included angle is provided between the second direction and an extension direction of the fifth side, and first included angles corresponding to the third sub-segments are different in at least part of the first signal lines.

9. The display panel according to claim 1, wherein
at least one of the pixel circuits comprises a first pixel circuit adjacent to one of the interval regions and comprising at least one first routing; and
in at least part of the first signal lines, in a direction perpendicular to a plane of the display panel, one of the first segments overlaps the at least one first routing, an orthographic projection of one of the second segments onto the plane of the display panel is adjacent to an orthographic projection of the at least one first routing onto the plane of the display panel, and a distance between the orthographic projection of the one of the second segments onto the plane of the display panel and the orthographic projection of the at least one first routing onto the plane of the display panel is greater than or equal to 1 μm.

10. The display panel according to claim 9,
wherein the first pixel circuit comprises a first transistor, the at least one first routing comprises a first-type of first routing, and the first-type of first routing is an active layer of the first transistor; and in at least part of the first signal lines, a part of one of the first segments is reused as a gate of the first transistor, the orthographic projection of the one of the second segments onto the plane of the display panel is adjacent to an orthographic projection of the first-type of first routing onto the plane of the display panel, and a distance between the orthographic projection of the one of the second segments onto the plane of the display panel and the orthographic projection of the first-type of first routing onto the plane of the display panel is greater than or equal to 1 μm; or
wherein the first pixel circuit comprises a second transistor, the at least one first routing comprises a second-type of first routing, and the second-type of first routing is electrically connected to the second transistor; and in at least part of the first signal lines, in the direction perpendicular to the plane of the display panel, the one of the first segments overlaps the second-type of first routing, the orthographic projection of the one of the second segments onto the plane of the display panel is adjacent to an orthographic projection of the second-type of first routing onto the plane of the display panel, and a distance between the orthographic projection of the one of the second segments onto the plane of the display panel and the orthographic projection of the second-type of first routing onto the plane of the display panel is greater than or equal to 1 μm.

11. The display panel according to claim 1, further comprising second signal lines extending in the first direction and located in the interval regions;
wherein in at least part of the first signal lines, at least one of the second segments comprises a first hollow, and in a direction perpendicular to a plane of the display panel, the first hollow overlaps at least one of the second signal lines; and/or
wherein at least part of the second signal lines each comprise a second hollow, and in the direction perpendicular to the plane of the display panel, the second hollow overlaps at least one of the second segments.

12. The display panel according to claim 11,
wherein the second signal lines comprise a first-type of second signal line for transmitting a variable-voltage signal and a second-type of second signal line for transmitting a constant-voltage signal; and in the direction perpendicular to the plane of the display panel, the first hollow overlaps with the first-type of second signal line, and the second-type of second signal line comprises the second hollow; or
wherein the second signal lines comprise a first-type of second signal line for transmitting a variable-voltage signal and a second-type of second signal line for transmitting a constant-voltage signal; and the first hollow comprises a first sub-hollow and a second sub-hollow, an area of the first sub-hollow is larger than an area of the second sub-hollow, and in the direction perpendicular to the plane of the display panel, the first sub-hollow overlaps the first-type of second signal line, and the second sub-hollow overlaps the second-type of second signal line.

13. The display panel according to claim 1, further comprising second signal lines extending in the first direction and located in the interval regions;
wherein in at least part of the first signal lines, at least one of the second segments comprises a fifth sub-segment and a sixth sub-segment; and in a direction perpendicular to a plane of the display panel, the fifth sub-segment does not overlap the second signal lines, the sixth sub-segment overlaps the second signal lines, and a width of the fifth sub-segment in the first direction is greater than a width of the sixth sub-segment in the first direction.

14. The display panel according to claim 1, wherein
the first signal lines comprise a fifth-type of first signal line, and in the fifth-type of first signal line, widths of at least part of the second segments in the first direction are different.

15. The display panel according to claim 14,
wherein a first connection line is connected between the fifth-type of first signal line and a first shift register, and a first via hole is provided between the fifth-type of first signal line and the first connection line; and in the fifth-type of first signal line, the second segments comprises a first-type of second segment and a second-type of second segment, a distance between the second-type of second segment and the first via hole is greater than a distance between the first-type of second segment and the first via hole, and a width of the second-type of second segment in the first direction is greater than a width of the first-type of second segment in the first direction; or
wherein in the fifth-type of first signal line, at least three second segments continuously arranged have a gradual change in width in the first direction; or
wherein the display panel has a first central axis extending in the first direction, and the display panel comprises two first display regions located on opposite sides of the first central axis; the display panel comprises first shift registers, at least one of the first shift registers comprises a plurality of first shift units that are cascaded, and the plurality of first shift units are located between adjacent circuit rows; the fifth-type of first signal line is electrically connected to two of the first shift registers, and the two of the first shift registers are respectively located in the two first display regions; the fifth-type of first signal line comprises two first parts, and the two first parts are respectively located in the two first display regions, each of the two first parts comprises a first sub-part and a second sub-part, and the second sub-part of one of the two first parts is connected between the first sub-part of the one of the two first parts and the other one of the two first parts;
the second segments in the first sub-part comprise a third-type of second segment and a fourth-type of second segment, a distance between the third-type of second segment and the first central axis is greater than a distance between the fourth-type of second segment and the first central axis, and a width of the third-type of second segment in the first direction is greater than a width of the fourth-type of second segment in the first direction; and the second segments in the second sub-part comprise a fifth-type of second segment and a sixth-type of second segment, a distance between the fifth-type of second segment and the first central axis is greater than a distance between the sixth-type of second segment and the first central axis, and a width of the fifth-type of second segment in the first direction is less than a width of the sixth-type of second segment in the first direction.

16. The display panel according to claim 1, further comprising a first shift register comprising a plurality of first shift units that are cascaded, and the plurality of first shift units are located between adjacent circuit rows;
wherein the first signal lines comprise a fifth-type of first signal line electrically connected to the plurality of first shift units; and
wherein the fifth-type of first signal line comprises a first signal sub-line and a second signal sub-line, a distance between the first signal sub-line and the plurality of first shift units connected thereto in the first direction is greater than a distance between the second signal sub-line and the plurality of first shift units connected thereto in the first direction, and a width of the second segments in the first signal sub-line in the first direction is greater than a width of the second segments in the second signal sub-line in the first direction.

17. The display panel according to claim 16, wherein
a first connection line is connected between the fifth-type of first signal line and the plurality of first shift units, and a line width of the first connection line connected to the first signal sub-line is greater than a line width of the first connection line connected to the second signal sub-line.

18. The display panel according to claim 1,
wherein at least one of the pixel circuits comprises a plurality of transistors, and at least part of the first signal lines are configured to provide signals to gates of the plurality of transistors; or
wherein at least one of the pixel circuits comprises a pulse width modulation module and a pulse amplitude modulation module; the pulse width modulation module comprises a first driving transistor, a first gate reset transistor, a first threshold compensation transistor, a first light-emitting control transistor, and a second light-emitting control transistor, wherein the first gate reset transistor is electrically connected between a first reset line and a gate of the first driving transistor, the first threshold compensation transistor is electrically connected between a second electrode of the first driving transistor and the gate of the first driving transistor, the first light-emitting control transistor is electrically connected between a first power line and a first electrode of the first driving transistor, and the second light-emitting control transistor is electrically connected between the second electrode of the first driving transistor and the pulse amplitude modulation module; the pulse amplitude modulation module comprises a second driving transistor, a second gate reset transistor, a second threshold compensation transistor, a third light-emitting control transistor, and a fourth light-emitting control transistor, wherein the second gate reset transistor is electrically connected between a second reset line and a gate of the second driving transistor, the second threshold compensation transistor is electrically connected between a second electrode of the second driving transistor and the gate of the first driving transistor, the third light-emitting control transistor is electrically connected between a second power line and a first electrode of the second driving transistor, and the second light-emitting control transistor is electrically connected between the second electrode of the second driving transistor and a light-emitting element; and wherein the first signal lines comprise: a first reset scanning line for providing a signal to a gate of the first gate reset transistor; and/or a first compensation scanning line for providing a signal to a gate of the first threshold compensation transistor; and/or a first light-emitting control scanning line for providing a signal to a gate of the first light-emitting control transistor and a gate of the second light-emitting control transistor; and/or a second reset scanning line for providing a signal to a gate of the second gate reset transistor; and/or a second compensation scanning line for providing a signal to a gate of the second threshold compensation transistor; and/or a second light-emitting control scanning line for providing a signal to a gate of the third light-emitting control transistor and a gate of the fourth light-emitting control transistor.

19. The display panel according to claim 1, wherein
at least one of the pixel circuits comprises a pulse width modulation module, and the pulse width modulation module comprises a first driving transistor and a first capacitor; and
the first signal lines comprise a frequency-sweep line electrically connected to a gate of the first driving transistor through the first capacitor.

20. A display apparatus, comprising a display panel, wherein the display panel comprises:
a plurality of circuit rows arranged in a first direction, wherein at least one circuit row of the plurality of circuit rows comprises circuit regions and interval regions alternately arranged in a second direction, the circuit regions comprise pixel circuits, and the first direction intersects the second direction; and
first signal lines extending in the second direction and electrically connected to the pixel circuits, wherein at least one of the first signal lines comprises first segments, at least one of which is located in one circuit region, and second segments, at least one of which is at least located in one interval region, and a width of at least part of the second segments in the first direction is greater than a width of at least part of the first segments in the first direction.
